(19) United States
(12) Patent Application Publication
(10) Pub. No.: US 2014/0202535 A1
(43) Pub. Date: Jul. 24, 2014

(54) SOLAR CELL MODULE

(71) Applicant: SANYO ELECTRIC CO., LTD., Osaka (JP)

(72) Inventor: Toshiyuki SAKUMA, Osaka (JP)

(73) Assignee: SANYO ELECTRIC CO., LTD., Osaka (JP)

(21) Appl. No.: 14/225,480

(22) Filed: Mar. 26, 2014

Related U.S. Application Data
(63) Continuation of application No. PCT/JP2012/078786, filed on Nov. 7, 2012.

(30) Foreign Application Priority Data
Nov. 11, 2011 (JP) 2011-247099

(51) Int. Cl. H01L 31/048

(52) U.S. Cl. CPC H01L 31/0481
USPC 136/259

(57) ABSTRACT

An aspect of the invention provides a solar cell module, which comprises a solar cell with a light-receiving surface and a back surface, a first protection member disposed at a light-receiving surface side of the solar cell and made of a glass plate, a second protection member disposed at a back surface side of the solar cell, and a filler layer provided between the first protection member and the second protection member and sealing the solar cell. At least part of a portion of the filler layer situated at the back surface side of the solar cell contains an acidic additive.

### CROSS REFERENCE TO RELATED APPLICATIONS

This application is a continuation application of PCT International Application No. PCT/JP2012/078786, filed on Nov. 7, 2012, entitled “SOLAR CELL MODULE”, which claims priority based on Article 8 of Patent Cooperation Treaty from prior Japanese Patent Applications No. 2011-247099, filed on Nov. 11, 2011, the entire contents of which are incorporated herein by reference.

### BACKGROUND ART

The invention relates to a solar cell module.

In recent years, solar cell modules as described in Patent Document 1 have been drawing attention as an environmentally-friendly energy source.

Such a solar cell module includes solar cells configured to generate electric power by receiving light. The solar cells are easily deteriorated by contact with moisture and the like. For this reason, the solar cells need to be isolated from the ambient air. To this end, the solar cells are usually sealed with a filler layer provided between a pair of protection members. At least one of the pair of protection members is made of glass.

PRIOR ART DOCUMENT PATENT DOCUMENT Patent Document 1: Japanese Patent Application Publication No. 2005-129926

### SUMMARY OF THE INVENTION

However, in such a solar cell module, an alkaline component such as Na coming out of a glass plate forming the protection member may sometimes alkalize the filler layer and yellow the filler layer.

One aspect of the invention provides a solar cell module in which a filler layer does not easily become yellowed.

A solar cell module of the embodiment includes a solar cell, a first protection member, a second protection member, and a filler layer. The solar cell has a light-receiving surface and a back surface. The first protection member is disposed at a light-receiving surface side of the solar cell. The first protection member is made of a glass plate. The second protection member is disposed at a back surface side of the solar cell. The filler layer is provided between the first protection member and the second protection member. The filler layer seals the solar cell. At least part of a portion of the filler layer situated at the back surface side of the solar cell contains an acidic additive.

According to the invention, a solar cell module in which a filler layer does not easily become yellowed can be provided.

### BRIEF DESCRIPTION OF THE DRAWING

FIG. 1 is a schematic cross-sectional view of a solar cell module according to an embodiment of the invention.

### EMBODIMENTS

Hereinbelow, an example of preferred embodiments of the invention is described. It is to be noted that the following embodiments are mere illustration of an example. The invention is not at all limited to the following embodiments.

Moreover, the drawing to be referred to in the embodiments is a schematic illustration, and the dimensional proportions and the like of objects depicted in the drawing may be different from the actual dimensional proportions and the like of the objects. The specific dimensional proportions and the like of the objects should be determined based on the following description.

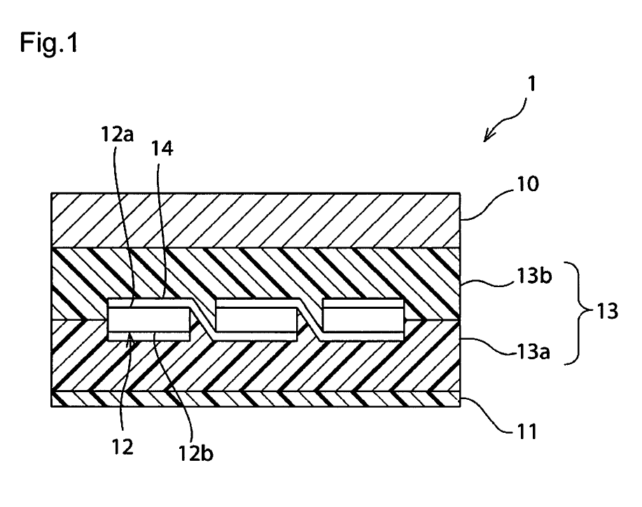

As illustrated in FIG. 1, solar cell module 1 includes solar cells 12. Each solar cell 12 has light-receiving surface 12a and back surface 12b. The type of solar cell 12 is not particularly limited. For example, solar cell 12 maybe a crystalline silicon solar cell, a thin film solar cell, or the like. Solar cell 12 may have a P-side electrode disposed at one main surface and an N-side electrode disposed at the other main surface. Alternatively, solar cell 12 may have both a P-side electrode and an N-side electrode at one main surface. Here, “light-receiving surface” refers to one of the two main surfaces of the solar cell, which mainly receives light. Solar cell 12 may be configured to generate electric power only when receiving light at light-receiving surface 12a, or configured to generate electric power not only when receiving light at light-receiving surface 12a but also when receiving light at back surface 12b. Solar cells 12 are electrically connected to each other by wiring materials 14.

First protection member 10 is disposed at the light-receiving surface 12a side of each solar cell 12. First protection member 10 can be made of a glass plate.

Second protection member 11 is disposed at the back surface 12b side of each solar cell 12. Second protection member 11 faces first protection member 10. Second protection member 11 can be made of a resin, for example. Second protection member 11 preferably contains a polyolefin resin and more preferably contains at least one of polyethylene resin and polypropylene resin. Second protection member 11 does preferably not include any metal layer made of aluminum or the like or any inorganic layer made of silica or the like.

Filler layer 13 is provided between first protection member 10 and second protection member 11. Filler layer 13 seals solar cells 12.

In this embodiment, filler layer 13 includes first filler layer 13a and second filler layer 13b. First filler layer 13a is provided between each solar cell 12 and second protection member 11. Second filler layer 13b is provided between each solar cell 12 and first protection member 10.

Filler layer 13 maybe made of a resin, for example. Filler layer 13 may be made solely of the resin or may contain a residue such for example as a crosslinking agent in addition to the resin.

Resin which filler layer 13 is made of is not particularly limited. However, filler layer 13 is preferably made, for example, of ethylene-vinyl acetate copolymer (EVA), a polyolefin resin such as polyethylene, or the like.

At least part of a portion of filler layer 13 situated at the light-receiving surface 12a side of solar cell 12 preferably contains a non-crosslinked resin. Specifically, second filler layer 13b preferably contains the non-crosslinked resin. In the invention, the non-crosslinked resin refers to a resin with a gel fraction of 50% or below. First filler layer 13a preferably contains a crosslinked resin. In the invention, the crosslinked resin refers to a resin with a gel fraction above 50%.

Note that in the invention, “gel fraction” is measured using the following measurement method. 1 g of the resin to be measured is prepared. This resin is immersed in 100 ml of xylene for 24 hours at 120° C. Then, the residue in the xylene is taken out and dried for 16 hours at 80° C. Then, the mass of the dried residue is measured. From the results thus obtained, the gel fraction (%) is calculated based on an equation (1) given below.

(Gel Fraction(%))=(Mass of Residue(g))/(Mass of Resin before Immersion(g)) (1)

At least part of a portion of filler layer 13 situated at the back surface 12b side of solar cell 12 contains an acidic additive. Specifically, first filler layer 13a contains the acidic additive. The acidic additive may be an additive which itself is an acidic component, or an additive that produces an acidic component through decomposition, or the like. Of the above acidic additives, examples of the acidic additive which itself is an acidic component include an N—OR type hindered amine light stabilizer, a pigment dispersed sol acidized using an ion-exchange resin, and the like. Of the above acidic additives, examples of the acidic additive which produces an acidic component through decomposition or the like include a phosphate-ester containing hindered phenol antioxidant, an ester-bond containing crosslinking agent, and the like. The at least part of the portion of filler layer 13 situated at the back surface 12b side of solar cell 12 may contain only one of the acidic additives or two or more of the acidic additives. Not only the at least part of but also other parts of the portion of filler layer 13 situated at the back surface 12b side of solar cell 12 may contain the above-described acidic additive.

As mentioned earlier, in a solar cell module, an alkaline component such as Na coming out of a glass plate forming a protection member may sometimes alkalize a filler layer and yellow the filler layer. This yellowing can be alleviated by exposing the filler layer to ultraviolet light. However, the filler layer situated at the back surface side of each solar cell does not easily get exposed to ultraviolet light. Thus, it is difficult to solve the yellowing particularly for the filler layer situated at the back surface side.

In view of this, in solar cell module 1, at least part of the portion of filler layer 13 situated at the back surface 12b side of solar cell 12 contains the acidic additive. Thus, even when an alkaline component coming out of the glass plate reaches the at least part of the portion of filler layer 13 situated at the back surface 12b side of solar cell 12, this part does not easily become alkalized. Accordingly, in solar cell module 1, filler layer 13 does not easily yellowed by the alkaline component.

In solar cell module 1, filler layer 13 is yellowed by the alkaline component even less easily in the case where not only the at least part of but also other parts of the portion of filler layer 13 situated at the back surface 12b side of solar cell 12 contain the acidic additive.

In the case where at least part of the portion of filler layer 13 situated at the light-receiving surface 12a side of solar cell 12 contains a non-crosslinked resin, this part is highly flexible when at high temperature, and the alkaline component can easily reach it. Thus, in this case, this embodiment, which is capable of suppressing the yellowing is effective.

In the case where second protection member 11 contains a polyolefin resin, the acidic component of the acidic additive does not easily become dispersed to second protection member 11 because the polarity of the polyolefin resin is low. Thus, it is possible to suppress decrease in the density of the acidic component of the acidic additive in the at least part of the portion of filler layer 13 situated at the light-receiving surface 12a side of solar cell 12.

In the case where second protection member 11 includes no metal layer, oxygen easily enters filler layer 13 from the outside of solar cell module 1 through second protection member 11. Thus, in filler layer 13, the acidic additive is decomposed, providing an acidic atmosphere inside the filler. Accordingly, the yellowing can be alleviated more easily.

1. A solar cell module, comprising:
a solar cell with a light-receiving surface and a back surface;
a first protection member disposed at a light-receiving surface side of the solar cell and made of a glass plate;
a second protection member disposed at a back surface side of the solar cell; and
a filler layer provided between the first protection member and the second protection member and sealing the solar cell,
wherein
at least part of a portion of the filler layer situated at the back surface side of the solar cell contains an acidic additive.

2. The solar cell module according to claim 1, wherein the acidic additive is at least one kind selected from a group including a light stabilizer, an antioxidant, a pigment dispersed sol, and a crosslinking agent.

3. The solar cell module according to claim 1, wherein at least part of a portion of the filler layer situated at the light-receiving surface side of the solar cell contains a non-crosslinked resin.

4. The solar cell module according to claim 2, wherein at least part of a portion of the filler layer situated at the light-receiving surface side of the solar cell contains a non-crosslinked resin.

5. The solar cell module according to claim 1, wherein the second protection member contains a polyolefin resin.

6. The solar cell module according to claim 2, wherein the second protection member contains a polyolefin resin.

7. The solar cell module according to claim 4, wherein the second protection member contains a polyolefin resin.

8. The solar cell module according to claim 1, wherein the second protection member includes no metal layer.
